(19) United States
(12) Patent Application Publication
(10) Pub. No.: US 2026/0239914 A1
(43) Pub. Date: Aug. 13, 2026

(54) SUBSTRATE PROCESSING METHOD, METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventor: Noriaki MICHITA, Toyama (JP)

(21) Appl. No.: 19/638,597

(22) Filed: Apr. 3, 2026

Related U.S. Application Data
(63) Continuation of application No. PCT/JP2024/036916, filed on Oct. 17, 2024.

(30) Foreign Application Priority Data
Jan. 24, 2024 (JP) 2024-008950

(51) Int. Cl. H10P 72/00; H05B 1/02; H05B 6/80; H10P 14/20

(52) U.S. Cl. CPC H10P 72/0436; H05B 1/0233; H05B 6/80; H10P 14/3802

(57) ABSTRACT

It is possible to perform a modification process while suppressing a heat diffusion. There is provided a technique that includes: preparing a substrate provided with at least a first film formed thereon; and modifying the substrate by supplying an electromagnetic wave to the substrate while maintaining a temperature of the substrate equal to or less than a predetermined temperature such that an absorption rate of the electromagnetic wave of the first film is higher than an absorption rate of the electromagnetic wave of the substrate.

### CROSS REFERENCE TO RELATED APPLICATIONS

This application is a bypass continuation application of PCT International Application No. PCT/JP2024/036916, filed on October 17, 2024, in the WIPO, the international application being based upon and claiming the benefit of priority from Japanese Patent Application No. 2024-008950, filed on January 24, 2024, in the Japanese Patent Office, the entire contents of which are hereby incorporated by reference.

### TECHNICAL FIELD

The present disclosure relates to a substrate processing method, a method of manufacturing a semiconductor device, a substrate processing apparatus and a non-transitory computer-readable recording medium.

### BACKGROUND

### Related Art

As a part of a manufacturing process of a semiconductor device, a modification process such as an annealing process may be performed. For example, the annealing process is performed by heating a substrate in a process chamber by using a heater (which is a heating structure) to change a composition or a crystal structure of a film formed on a surface of the substrate or to restore a defect such as a crystal defect in the film. As a method of performing the modification process, a heat treatment process using an electromagnetic wave may be performed according to some related arts.

In the heat treatment process using the electromagnetic wave described above, a heat may be diffused (that is, a heat diffusion (also referred to as a “thermal diffusion”) may occur) from the film to be processed to a film other than the film to be processed.

### SUMMARY

According to the present disclosure, there is provided a technique capable of performing a modification process while suppressing a heat diffusion.

According to the embodiments of the present disclosure, there is provided a technique that includes: preparing a substrate provided with at least a first film formed thereon; and modifying the substrate by supplying an electromagnetic wave to the substrate for a temperature of the substrate to be equal to or less than a predetermined temperature such that an absorption rate of the electromagnetic wave of the first film is higher than an absorption rate of the electromagnetic wave of the substrate.

### BRIEF DESCRIPTION OF THE DRAWINGS

FIG. 1 is a diagram schematically illustrating a vertical cross-section of a process furnace of a substrate processing apparatus according to one or more embodiments of the present disclosure.

FIG. 2 is a diagram schematically illustrating a vertical cross-section of the substrate processing apparatus (which includes the process furnace) according to the embodiments of the present disclosure.

FIG. 3 is a diagram schematically illustrating a horizontal cross-section of the substrate processing apparatus according to the embodiments of the present disclosure.

FIG. 4 is a block diagram schematically illustrating a configuration of a controller and its related components of the substrate processing apparatus according to the embodiments of the present disclosure.

FIG. 5 is a diagram schematically illustrating an example of a waveform in which a microwave power supply preferably used in the embodiments of the present disclosure is pulse-controlled.

FIG. 6 is a flow chart schematically illustrating an example of a setting process for the microwave power supply preferably used in the embodiments of the present disclosure.

FIG. 7 is a flow chart schematically illustrating an exemplary process flow of a substrate processing according to the embodiments of the present disclosure.

FIG. 8 is a diagram schematically illustrating a cross-section of a structure of a film on a substrate preferably used in the embodiments of the present disclosure.

### DETAILED DESCRIPTION

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary. Further, the number of each component described in the present specification is not limited to one, and the number of each component described in the present specification may be two or more unless otherwise specified in the present specification.

### 1. Configuration of Substrate Processing Apparatus

The present embodiments will be described by way of an example in which a substrate processing apparatus 100 is configured as a single wafer type heat treatment apparatus capable of performing various kinds of heat treatment processes on a wafer 200 or a plurality of wafers including the wafer 200. Hereinafter, the plurality of wafers including the wafer 200 may also be simply referred to as “wafers 200”. For example, in the present embodiments, the substrate processing apparatus 100 is configured as an apparatus capable of performing an annealing process (modification process) by using an electromagnetic wave described later. In the substrate processing apparatus 100 according to the present embodiments, a FOUP (Front Opening Unified Pod, hereinafter, also referred to as a “pod”) 110 is used as a storage container (also referred to as a “carrier”) in which the wafer 200 is accommodated. The pod 110 is also used as a transfer container when the wafer 200 is transferred between various substrate processing apparatuses including the substrate processing apparatus 100.

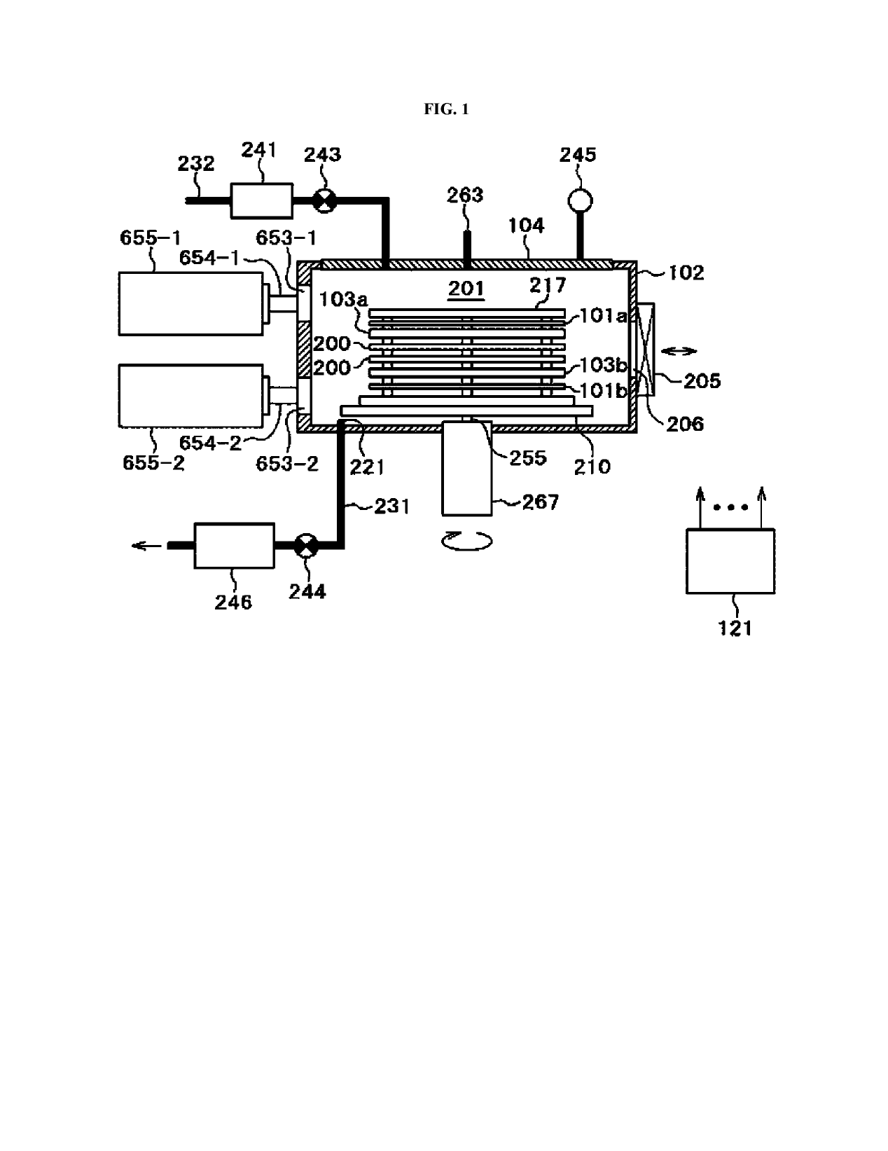

As shown in FIGS. 1, 2 and 3, the substrate processing apparatus 100 may include: a transfer housing 202 with a transfer chamber (also referred to as a “transfer region”) 203 provided therein; and cases 102-1 and 102-2 with process chambers 201-1 and 201-2 provided therein, respectively. The wafer 200 is transferred into or out of the transfer chamber 203. The cases 102-1 and 102-2 are provided on a side wall of the transfer housing 202. The cases 102-1 and 102-2 serve as a process vessel which will be described later. For example, the wafers 200 are processed in the process chambers 201-1 and 201-2. Further, a cooling case 109 constituting a cooling chamber 204 is provided between the process chambers 201-1 and 201-2.

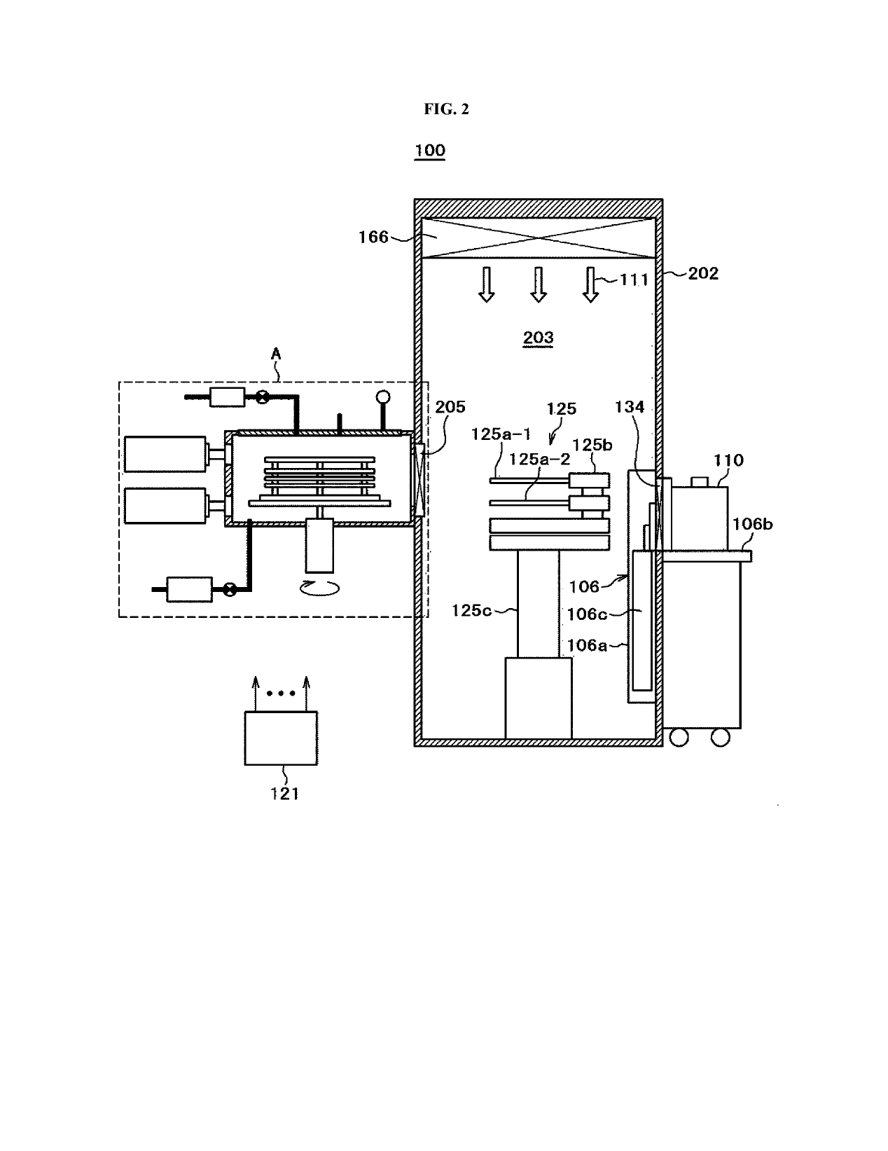

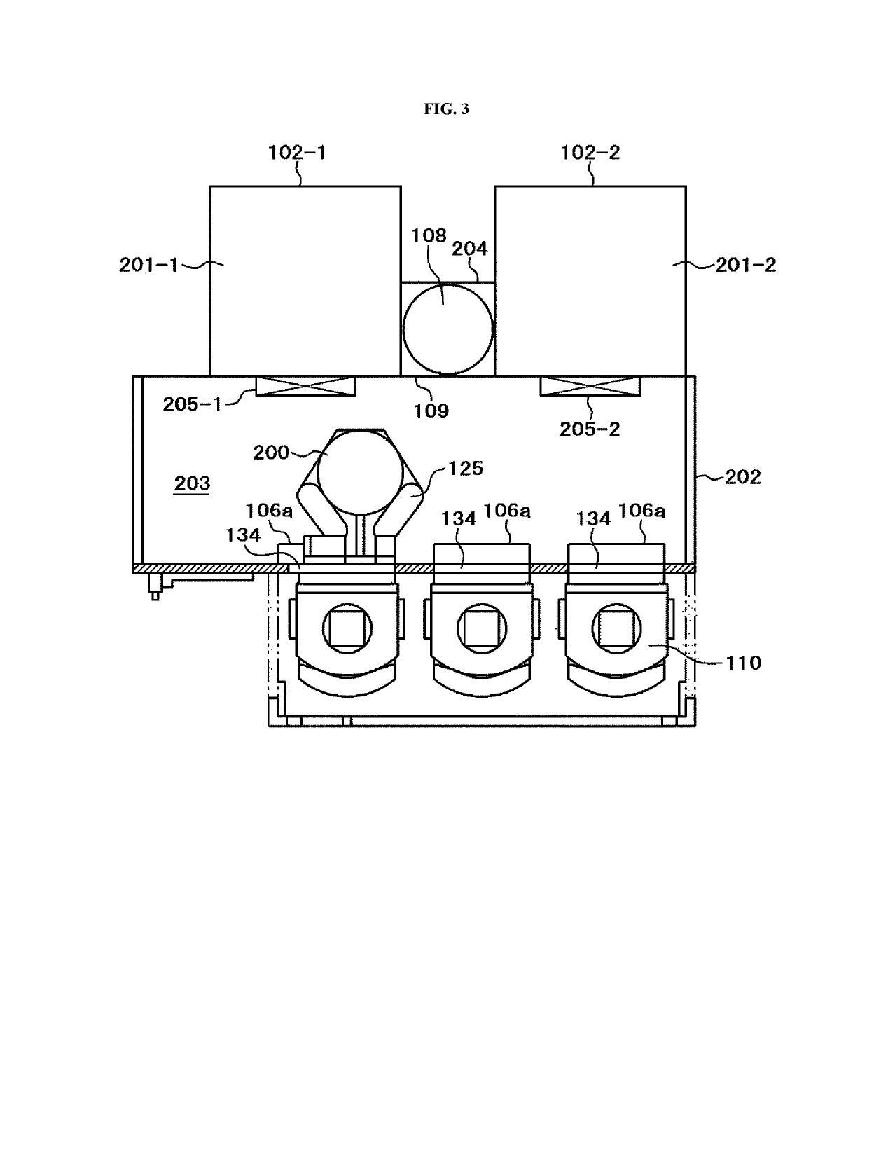

A loading port structure (also referred as an “LP”) 106 serving as a pod opening/closing structure capable of opening and closing a lid (not shown) of the pod 110 so as to transfer the wafer 200 into and out of the transfer chamber 203 is provided at a front side of the transfer housing 202. That is, the loading port structure 106 is shown in a right portion of FIG. 2 (a lower portion of FIG. 3). The loading port structure 106 includes a housing 106a, a stage 106b and an opener 106c. The stage 106b is configured to transfer the pod 110 to a position close to a substrate loading/unloading port 134 provided at the front side of the transfer housing 202 of the transfer chamber 203 while the pod 110 is placed on the stage 106b. The opener 106c is configured to open and close the lid (not shown) provided in the pod 110. In addition, the loading port structure 106 may be configured to be capable of purging an inside (inner portion) of the pod 110 with a purge gas 111 such as N₂ gas. In addition, the transfer housing 202 includes a purge gas circulation structure (which will be described later) capable of circulating the purge gas 111 such as the N₂ gas in the transfer chamber 203 by using a fan 166.

Gate valves (GVs) 205-1 and 205-2 capable of opening and closing the process chambers 201-1 and 201-2, respectively, are provided at a rear side of the transfer housing 202. That is, the gate valves 205-1 and 205-2 are shown in a left portion of FIG. 2 (an upper portion of FIG. 3). A transfer device 125 serving as a substrate transfer structure (also referred to as a “substrate transfer robot” or a “substrate transfer device”) capable of transferring the wafer 200 is provided in the transfer chamber 203. The transfer device 125 may include: tweezers 125a-1 and 125a-2 serving as a placement structure on which the wafers 200 are placed, respectively; a transfer structure 125b capable of rotating or linearly moving each of the tweezers 125a-1 and 125a-2 in a horizontal direction; and a transfer structure elevator 125c capable of elevating and lowering the transfer structure 125b. By consecutive operations of the tweezers 125a-1 and 125a-2, the transfer structure 125b and the transfer structure elevator 125c, it is possible to charge (or load) or discharge (or unload) the wafer 200 into or out of a component such as a boat 217 (which serves as a substrate retainer or a substrate support) described later, the cooling chamber 204 and the pod 110. Hereinafter, unless they need to be distinguished separately, the cases 102-1 and 102-2 may be collectively or individually referred to as a “case 102”, the process chambers 201-1 and 201-2 may be collectively or individually referred to as a “process chamber 201”, the gate valves 205-1 and 205-2 may be collectively or individually referred to as a “gate valve 205” and the tweezers 125a-1 and 125a-2 may be collectively or individually referred to as “tweezers 125a”.

The tweezers 125a-1 are made of ordinary aluminum, and are used for transferring a wafer at a low temperature or a normal temperature. The tweezers 125a-2 are made of a material (such as alumina and quartz) whose heat resistance is high and whose thermal conductivity is low (poor), and are used to transfer a wafer at a high temperature or the normal temperature. In other words, the tweezers 125a-1 are used for transferring the wafer at the low temperature and the tweezers 125a-2 are used for transferring the wafer at the high temperature. The tweezers 125a-2 used for transferring the wafer at the high temperature are configured such that, for example, the heat resistance of the tweezers 125a-2 is preferably 100 °C or higher, more preferably 200 °C or higher. A mapping sensor (not shown) may be installed in the tweezers 125a-1 used for transferring the wafer at the low temperature. By providing the tweezers 125a-1 used for transferring the wafer at the low temperature with the mapping sensor, it is possible to check (or confirm) the number of the wafers 200 in the loading port structure 106, the number of the wafers 200 in the process chamber 201, and the number of the wafers 200 in the cooling chamber 204.

The present embodiments will be described by way of an example in which the tweezers 125a-1 are used for transferring the wafer at the low temperature and the tweezers 125a-2 are used for transferring the wafer at the high temperature in the substrate processing apparatus 100. However, the present embodiments are not limited thereto. For example, the tweezers 125a-1 may be made of the material (such as alumina and quartz) whose heat resistance is high and whose thermal conductivity is low (poor) and may be used to transfer the wafer at the high temperature or the normal temperature, and the tweezers 125a-2 may be made of the ordinary aluminum and may be used for transferring the wafer at the low temperature or the normal temperature. Alternatively, both of the tweezers 125a-1 and the tweezers 125a-2 may be made of the material (such as alumina and quartz) whose heat resistance is high and whose thermal conductivity is low (poor).

### Process Furnace

A process furnace (that is, the process chamber 201) provided with a substrate processing structure as shown in FIG. 1 is disposed in a region (area) “A” surrounded by a broken line in FIG. 2. As shown in FIG. 3, although a plurality of process furnaces are provided according to the present embodiments, one process furnace will be described and the detailed descriptions of the other process furnaces will be omitted since configurations of the plurality of process furnaces are substantially the same.

As shown in FIG. 1, the process furnace includes the case 102 serving as a cavity (process vessel) made of a material such as a metal capable of reflecting the electromagnetic wave. In addition, a cap flange (which is a closing plate) 104 made of a metal material is provided so as to close (or seal) an upper end of the case 102 via an O-ring (not shown) serving as a seal. The process chamber 201 in which the wafer 200 is processed is constituted mainly by an inner space enclosed by the case 102 and the cap flange 104. A reaction tube (not shown) made of quartz capable of transmitting the electromagnetic wave may be provided in the case 102. When the reaction tube is provided in the case 102, the process vessel (that is, the case 102) may be configured such that the process chamber 201 is constituted by an inner space of the reaction tube. Alternatively, the process furnace may not be provided with the cap flange 104. When the cap flange 104 is not provided in the process furnace, the process chamber 201 may be defined by the case 102 with a closed ceiling.

A mounting table (which is a placement table) 210 is provided in the process chamber 201. The boat 217 serving as the substrate retainer (or the substrate support) configured to hold (support or accommodate) the wafers 200 is placed on an upper surface of the mounting table 210. The wafers 200 to be processed and susceptors 103a and 103b are accommodated in the boat 217. The susceptors 103a and 103b are placed with a predetermined interval therebetween to be vertically higher than and lower than the wafers 200, respectively, such that the wafers 200 are interposed therebetween. For example, a silicon plate (also referred to as a “Si plate”) or a silicon carbide plate (also referred to as a “SiC plate”) may be used as each of the susceptors 103a and 103b. By providing the susceptors 103a and 103b above and below the wafer 200 (or the wafers 200), it is possible to prevent an electric field intensity from being concentrated on an edge of the wafer 200. That is, the susceptors 103a and 103b are configured to suppress the absorption of the electromagnetic wave into the edge of the wafer 200. In addition, quartz plates 101a and 101b serving as heat insulating plates may be placed with a predetermined interval therebetween such that the quartz plate 101a is provided above an upper surface of the susceptor 103a and the quartz plate 101b is provided below a lower surface of the susceptor 103b. According to the present embodiments, the quartz plate 101a and the quartz plate 101b are substantially identical to each other, and the susceptor 103a and the susceptor 103b are substantially identical to each other. Therefore, in the present embodiments, the quartz plate 101a and 101b may be collectively or individually referred to as a “quartz plate 101” unless they need to be distinguished separately, and the susceptor 103a and 103b may be collectively or individually referred to as a “susceptor 103” unless they need to be distinguished separately. The boat 217 is configured to be capable of supporting (holding) the wafers 200. Thereby, it is possible to improve a processing capability.

For example, the case 102 serving as the process vessel is a flat and sealed vessel with a horizontal cross-section of a circular shape. In addition, the transfer housing 202 serving as a lower vessel is made of a metal material such as aluminum (Al) and stainless steel (SUS) or a material such as quartz. Further, a space surrounded by the case 102 may be referred to as a “reaction region 201” or “the process chamber 201” serving as a process space, and a space surrounded by the transfer housing 202 may be referred to as the “transfer region 203” or the “transfer chamber 203” serving as a transfer space. While the process chamber 201 and the transfer chamber 203 are adjacent to each other in the horizontal direction according to the present embodiments, the present embodiments are not limited thereto. For example, the process chamber 201 and the transfer region 203 may be adjacent to each other in a vertical direction such that a substrate retainer of a predetermined structure is capable of being elevated or lowered.

As shown in FIGS. 1, 2 and 3, a substrate loading/unloading port 206 is provided at a side surface of the transfer housing 202 to be adjacent to the gate valve 205. The wafer 200 is moved (transferred) between the process chamber 201 and the transfer chamber 203 through the substrate loading/unloading port 206. Around the gate valve 205 or the substrate loading/unloading port 206, a choke structure whose length is 1/4 wavelength of the electromagnetic wave is provided as a countermeasure against a leakage of the electromagnetic wave as described later.

An electromagnetic wave supplier (which is an electromagnetic wave supply structure or an electromagnetic wave supply apparatus) serving as a heater (which is a heating structure) described later is provided at a side surface of the case 102. The electromagnetic wave such as a microwave supplied through the electromagnetic wave supplier is introduced (supplied) into the process chamber 201 to heat a component such as the wafer 200 and to process the wafer 200. The electromagnetic wave supplier is provided at a position opposite to the substrate loading/unloading port 206.

The mounting table 210 is supported by a shaft 255 serving as a rotating shaft. The shaft 255 penetrates a bottom of the process chamber 201 and is connected to a driver (which is a driving structure) 267 at an outside (outer portion) of process chamber 201. The driver 267 is configured to rotate the shaft 255. The wafer 200 accommodated in the boat 217 may be rotated by rotating the shaft 255 and the mounting table 210 by operating the driver 267. In addition, a bellows (not shown) covers a lower end portion of the shaft 255 to maintain an inside (inner portion) of the process chamber 201 and an inside (inner portion) of the transfer region 203 airtight.

According to the present embodiments, the driver 267 is configured to elevate and lower the mounting table 210. By operating the driver 267 based on a height of the substrate loading/unloading port 206, the mounting table 210 may be elevated or lowered until the wafer 200 reaches a wafer transfer position when the wafer 200 is transferred, and the mounting table 210 may be elevated or lowered until the wafer 200 reaches a processing position in the process chamber 201 (hereinafter, also referred to as a “wafer processing position”) when the wafer 200 is processed.

An exhauster (which is an exhaust structure or an exhaust system) configured to exhaust an atmosphere (inner atmosphere) of the process chamber 201 is provided below the process chamber 201 on an outer circumference of the mounting table 210. As shown in FIG. 1, an exhaust port 221 is provided in the exhauster. An exhaust pipe 231 is connected to the exhaust port 221. A pressure regulator (which is a pressure adjusting structure) 244 such as an APC (Automatic Pressure Controller) valve and a vacuum pump 246 are sequentially connected to the exhaust pipe 231 in series. For example, the APC valve is configured to adjust an opening degree thereof in accordance with a pressure (inner pressure) of the process chamber 201.

According to the present embodiments, for example, the APC valve is used as the pressure regulator 244. However, in the embodiments, the pressure regulator 244 is not limited to the APC valve. The pressure regulator 244 may be embodied by a combination of a conventional opening/closing valve and a pressure regulating valve so long as it is possible to receive information on the inner pressure of the process chamber 201 (and/or to receive a feedback signal from a pressure sensor 245 which will be described later, for example) and to adjust an exhaust amount based on the received information. In the present specification, the pressure regulator 244 may also be referred to as the APC valve 244.

The exhauster (also referred to as the “exhaust system” or an “exhaust line”) is constituted mainly by the exhaust port 221, the exhaust pipe 231 and the pressure regulator 244. It is also possible to further provide an exhaust port to surround the mounting table 210 such that a gas can be exhausted from an entire circumference of the wafer 200 through the exhaust port surrounding the mounting table 210. The exhauster may further include the vacuum pump 246.

The cap flange 104 is provided with a gas supply pipe 232 through which a process gas such as an inert gas, a source gas and a reactive gas used for performing various substrate processing is supplied into the process chamber 201. A mass flow controller (MFC) 241 serving as a flow rate controller (flow rate control structure) and a valve 243 serving as an opening/closing valve are sequentially installed at the gas supply pipe 232 in this order from an upstream side to a downstream side of the gas supply pipe 232 in a gas flow direction. For example, a nitrogen (N₂) gas supply source serving as an inert gas supply source (not shown) is connected to the upstream side of the gas supply pipe 232 such that the N₂ gas (inert gas) can be supplied into the process chamber 201 via the MFC 241 and the valve 243. When two or more kinds of gases are used for the substrate processing, it is possible to supply the gases into the process chamber 201 by connecting one or more gas supply pipes to the gas supply pipe 232 at a downstream side of the valve 243 provided at the gas supply pipe 232. The gas supply source may be regarded to be included in a gas supplier that will be described later. An MFC serving as a flow rate controller and a valve serving as an opening/closing valve may be sequentially installed at each of the one or more gas supply pipes in this order from an upstream side to a downstream side of each of the one or more gas supply pipes in the gas flow direction. Alternatively, different gas supply pipes, each provided with an MFC and a valve, may be separately provided for each type of the gases.

A gas supplier (which is a gas supply structure or a gas supply system) is constituted mainly by the gas supply pipe 232, the MFC 241 and the valve 243. The gas supplier may further include a gas supply source such as the nitrogen (N₂) gas supply source. When the inert gas is supplied through the gas supplier, the gas supplier may also be referred to as an inert gas supplier (which is an inert gas supply structure or an inert gas supply system).

A temperature sensor 263 serving as a non-contact type temperature detector (which is a temperature measuring structure) is provided at the cap flange 104. By adjusting an output of a microwave oscillator 655 which will be described later based on temperature information detected by the temperature sensor 263, the wafer 200 serving as the substrate is heated such that a desired temperature distribution of a temperature of the wafer 200 can be obtained. For example, the temperature sensor 263 is constituted by a radiation thermometer such as an IR (Infrared Radiation) sensor. The temperature sensor 263 is provided so as to measure a surface temperature of the quartz plate 101a or a surface temperature of the wafer 200. When the susceptor 103 (which serves as a heating element) described above is provided, the temperature sensor 263 may be configured to measure a surface temperature of the susceptor 103. In the present embodiments, the term “temperature of the wafer 200” or “wafer temperature” may refer to a wafer temperature converted by using temperature conversion data described later (that is, an estimated wafer temperature), may refer to a temperature obtained directly by measuring the temperature of the wafer 200 by the temperature sensor 263, or may refer to both of them.

By acquiring transition data of a temperature change of the quartz plate 101 (or the susceptor 103) and the wafer 200 in advance by the temperature sensor 263, the temperature conversion data indicating a correlation between a temperature of the quartz plate 101 (or the susceptor 103) and the temperature of the wafer 200 may be stored in a memory 121c or may be stored in an external memory 123, which will be described later. By preparing the temperature conversion data in advance as described above, it is possible to estimate the temperature of the wafer 200 by measuring the temperature of the quartz plate 101 (or the susceptor 103) alone, and it is also possible to control the output of the microwave oscillator 655 (that is, to control the heater) based on the estimated temperature of the wafer 200.

While the radiation thermometer is exemplified above as the temperature sensor 263 serving as the temperature detector measuring the temperature of the wafer 200 serving as the substrate according to the present embodiments, the present embodiments are not limited thereto. A thermocouple may be used as the temperature sensor 263 to measure the temperature of the wafer 200, or both the thermocouple and the non-contact type temperature detector (non-contact type thermometer) may be used as the temperature sensor 263 to measure the temperature of the wafer 200. However, when the thermocouple is used as the temperature sensor 263 to measure the temperature of the wafer 200, it is preferable to provide (dispose) the thermocouple in the vicinity of the wafer 200 to measure the temperature the wafer 200. That is, since it is preferable to dispose the thermocouple in the process chamber 201, the thermocouple itself may be heated by the microwave supplied from the microwave oscillator 655 described later. As a result, it may not be possible to accurately measure the temperature of the wafer 200 using the thermocouple. Therefore, it is preferable to use the non-contact type thermometer as the temperature sensor 263.

While the temperature sensor 263 is provided at the cap flange 104 according to the present embodiments, the present embodiments are not limited thereto. For example, the temperature sensor 263 may be provided at the mounting table 210. While the temperature sensor 263 is directly disposed at the cap flange 104 or the mounting table 210 according to the present embodiments, the present embodiments are not limited thereto. For example, the temperature sensor 263 may measure the temperature of the wafer 200 indirectly by measuring the radiated light reflected by a component such as a mirror and emitted through a measurement window provided in the cap flange 104 or the mounting table 210. While the temperature sensor 263 is provided according to the present embodiments, the present embodiments are not limited thereto. A plurality of temperature sensors including the temperature sensor 263 may be provided according to the present embodiments.

Electromagnetic wave introduction ports (microwave introduction ports) 653-1 and 653-2 are provided at the side wall of the case 102. One end of a waveguide 654-1 and one end of a waveguide 654-2 through which the electromagnetic wave (microwave) is supplied into the process chamber 201 are connected to the electromagnetic wave introduction ports 653-1 and 653-2, respectively. The other end of the waveguide 654-1 and the other end of the waveguide 654-2 are connected to microwave oscillators (hereinafter, also referred to as electromagnetic wave sources or electromagnetic wave oscillators) 655-1 and 655-2, respectively, serving as heating sources configured to supply the electromagnetic wave into the process chamber 201 to heat the process chamber 201. The microwave oscillators 655-1 and 655-2 are configured to supply the electromagnetic wave such as the microwave to the waveguides 654-1 and 654-2, respectively. For example, a magnetron or a klystron may be used as each of the microwave oscillators 655-1 and 655-2. In the present specification, unless they need to be distinguished separately, the electromagnetic wave introduction ports 653-1 and 653-2 may be collectively or individually referred to as an “electromagnetic wave introduction port 653”, the waveguides 654-1 and 654-2 may be collectively or individually referred to as a “waveguide 654”, and the microwave oscillators 655-1 and 655-2 may be collectively or individually referred to as the “microwave oscillator 655”.

Preferably, a frequency of the electromagnetic wave generated by the microwave oscillator 655 is controlled such that the frequency is within a range from 13.56 MHz to 24.125 GHz. More preferably, the frequency is controlled to be a frequency of 2.45 GHz or 5.8 GHz. In the present embodiments, the frequency of each of the microwave oscillators 655-1 and 655-2 may be the same or may be different.

While the two microwave oscillators 655-1 and 655-2 are provided on the same side surface of the case 102 according to the present embodiments, the present embodiments are not limited thereto. For example, it is sufficient as long as at least one microwave oscillator may be provided according to the present embodiments. For example, the microwave oscillator 655 may be provided on another surface other than the side surface of the case 102 shown in FIG. 1. The electromagnetic wave supplier (also referred to as the “electromagnetic wave supply structure” or the “electromagnetic wave supply apparatus”) serving as the heater is constituted mainly by the microwave oscillators 655-1 and 655-2, the waveguides 654-1 and 654-2 and the electromagnetic wave introduction ports 653-1 and 653-2. The electromagnetic wave supplier may also be referred to as a “microwave supplier” which is a microwave supply structure or a microwave supply apparatus.

A controller 121 which will be described later is connected to each of the microwave oscillators 655-1 and 655-2. The temperature sensor 263 configured to measure the temperature of the wafer 200 or the temperature of the quartz plate 101a (or the quartz plate 101b) accommodated in the process chamber 201 is connected to the controller 121. The temperature sensor 263 is configured to measure the temperature of the quartz plate 101 or the wafer 200 in a manner described above and to transmit the measured temperature to the controller 121. The controller 121 is configured to be capable of controlling a heating of the wafer 200 by controlling the outputs of the microwave oscillators 655-1 and 655-2. As a method of controlling the heating by the heater, for example, a method of controlling the heating of the wafer 200 by controlling a voltage input to the microwave oscillator 655, or a method of controlling the heating of the wafer 200 by changing a ratio of a turn-on time (that is, a time duration during which a power of the microwave oscillator 655 is turned on) and a turn-off time (that is, a time duration during which the power of the microwave oscillator 655 is turned off) may be used. That is, the controller 121 is configured to be capable of controlling a turn-on operation and a turn-off operation for the electromagnetic wave generated by the microwave oscillator 655.

According to the present embodiments, for example, the microwave oscillators 655-1 and 655-2 are controlled by the same control signal transmitted from the controller 121. However, the present embodiments are not limited thereto. For example, the microwave oscillator 655-1 and the microwave oscillator 655-2 may be individually controlled by individual control signals transmitted from the controller 121 to the microwave oscillator 655-1 and the microwave oscillator 655-2, respectively.

### Controller

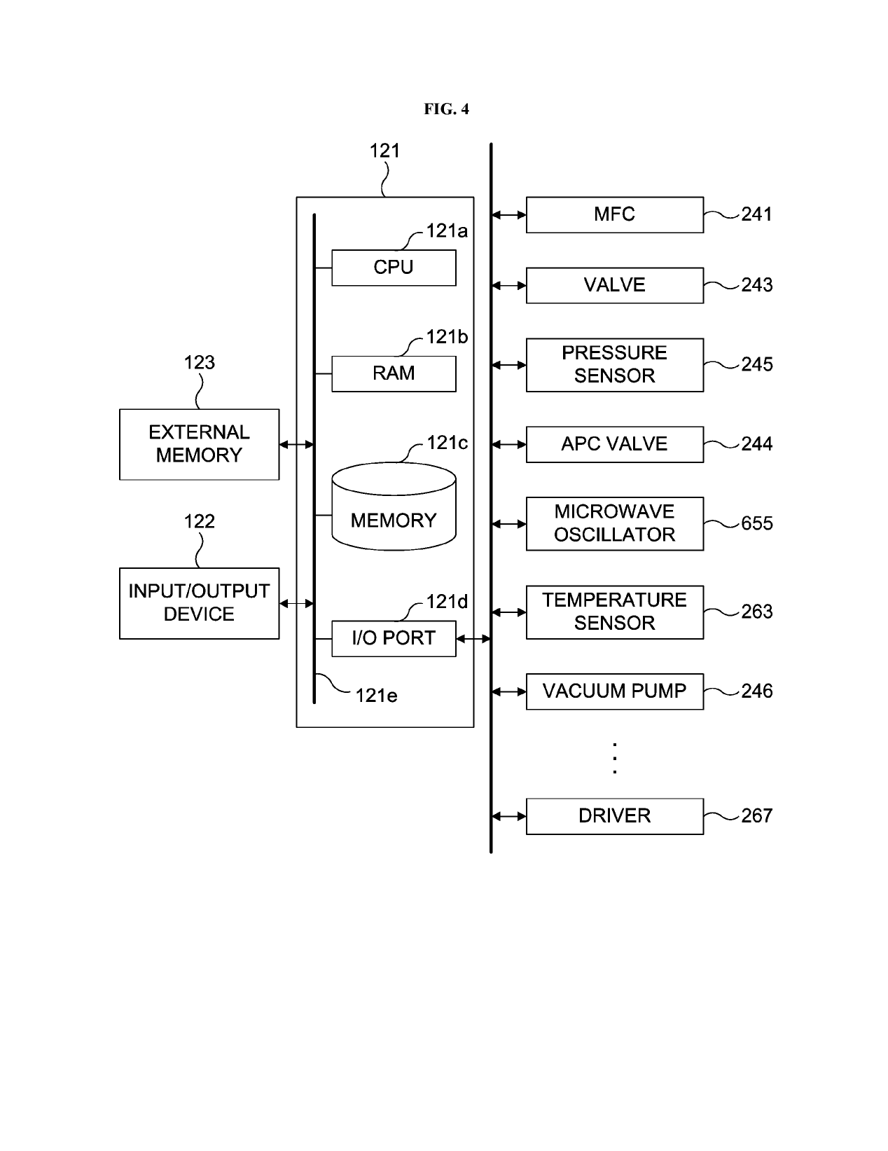

As shown in FIG. 4, the controller 121 serving as a control structure (or a control apparatus) may be constituted by a computer including a CPU (Central Processing Unit) 121a, a RAM (Random Access Memory) 121b, the memory 121c and an I/O port (input/output port) 121d. The RAM 121b, the memory 121c and the I/O port 121d are configured to be capable of exchanging data with the CPU 121a through an internal bus 121e. For example, an input/output device 122 constituted by a component such as a touch panel is connected to the controller 121.

For example, the memory 121c is configured by a component such as a flash memory and an HDD (Hard Disk Drive). For example, a control program configured to control operations of the substrate processing apparatus 100 and a process recipe containing information on sequences (procedures) and conditions of the annealing process (modification process) of the substrate processing described later may be readably stored in the memory 121c. The process recipe is obtained by combining steps of the substrate processing described later such that the controller 121 can execute the steps to acquire a predetermined result, and functions as a program. Hereinafter, the process recipe and the control program are collectively or individually referred to as a “program.” In addition, the process recipe may also be simply referred to as a “recipe.”

In the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the MFC 241, the valve 243, the pressure sensor 245, the APC valve 244, the vacuum pump 246, the temperature sensor 263, the driver 267 (including the transfer device 125) and the microwave oscillator 655.

The CPU 121a is configured to read the control program from the memory 121c and execute the control program read from the memory 121c. Furthermore, the CPU 121a is configured to read the recipe from the memory 121c in accordance with an operation command inputted from the input/output device 122. In accordance with the contents of the recipe read from the memory 121c, the CPU 121a may be configured to control various operations such as a transfer operation for the substrate (that is, the wafer 200) by the transfer device 125, a flow rate adjusting operation for various gases by the MFC 241, an opening and closing operation of the valve 243, a pressure adjusting operation by the APC valve 244 based on the pressure sensor 245, a start and stop of the vacuum pump 246, an output adjusting operation by the microwave oscillator 655 based on the temperature sensor 263, the turn-on operation and the turn-off operation for the microwave outputted by the microwave oscillator 655, an operation of adjusting a rotation and a rotation speed of the mounting table 210 (or an operation of adjusting rotation and rotation speed of the boat 217) by the driver 267, and an elevating and lowering operation of the mounting table 210 (or an elevating and lowering operation of the boat 217) by the driver 267.

The controller 121 may be embodied by installing the above-described program stored in the external memory 123 into a computer. For example, the external memory 123 may include a magnetic disk such as a hard disk, an optical disk such as a CD, a magneto-optical disk such as an MO and a semiconductor memory such as a USB memory. The memory 121c or the external memory 123 may be embodied by a non-transitory computer readable recording medium. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication interface such as the Internet and a dedicated line may be used for providing the program to the computer.

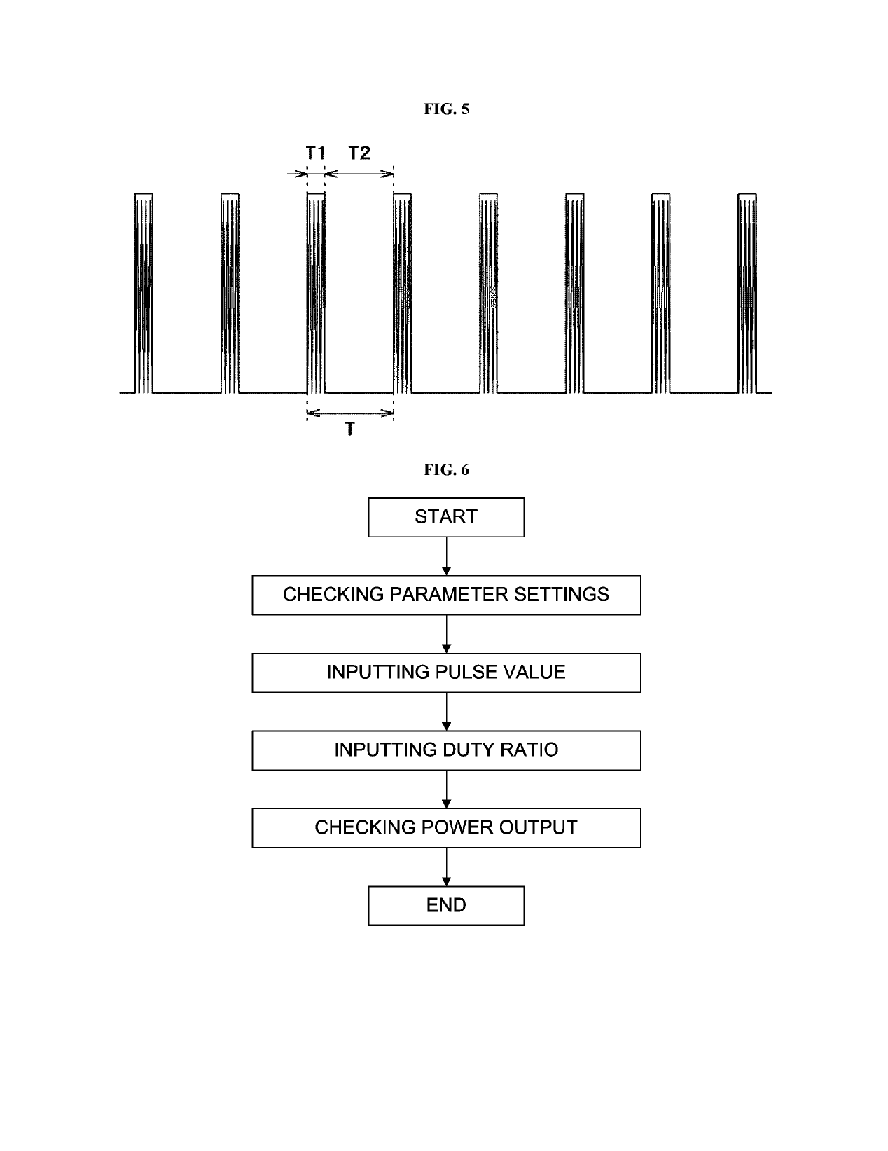

As shown in FIG. 5, the microwave oscillator 655 is configured to supply the electromagnetic wave in a pulsed manner (that is, a supply of the electromagnetic wave is alternately turned on and off in a short period of time) in which the electromagnetic wave is turned on (ON) for a first predetermined time (“T1” shown in FIG. 5) and turned off (OFF) for a second predetermined time (“T2” shown in FIG. 5). In the present embodiments, the first predetermined time T1 and the second predetermined time T2 can be varied (changed). For example, the second predetermined time T2 may be set to be longer than the first predetermined time T1. For example, a pulse frequency can be set to a frequency within a range from 1 kHz to 100 kHz. In other words, a pulse period (T) (which is obtained by adding the first predetermined time T1 to the second predetermined time T2) can be set to a period within a range from 10 microseconds to 1 second. Further, for example, a duty ratio (D) (which is obtained by dividing the first predetermined time T1 by the pulse period T) can be set to a ratio within a range from 10 % to 90 %. By setting parameters as described above, the electromagnetic wave corresponding to a power supply frequency (for example, 2.45 GHz) is outputted, and an amount of an output power per unit time is reduced depending on a value of the duty ratio D.

The pulse frequency and the duty ratio D of the electromagnetic wave outputted from the microwave oscillator 655 can be set by using the input/output device 122. In a setting process for the electromagnetic wave, as shown in FIG. 6, an operator (operating personnel) first checks (or confirms) parameter settings, then inputs a pulse value (for example, the pulse frequency) and the duty ratio D, and finally checks (or confirms) a power output.

### 2. Substrate Processing

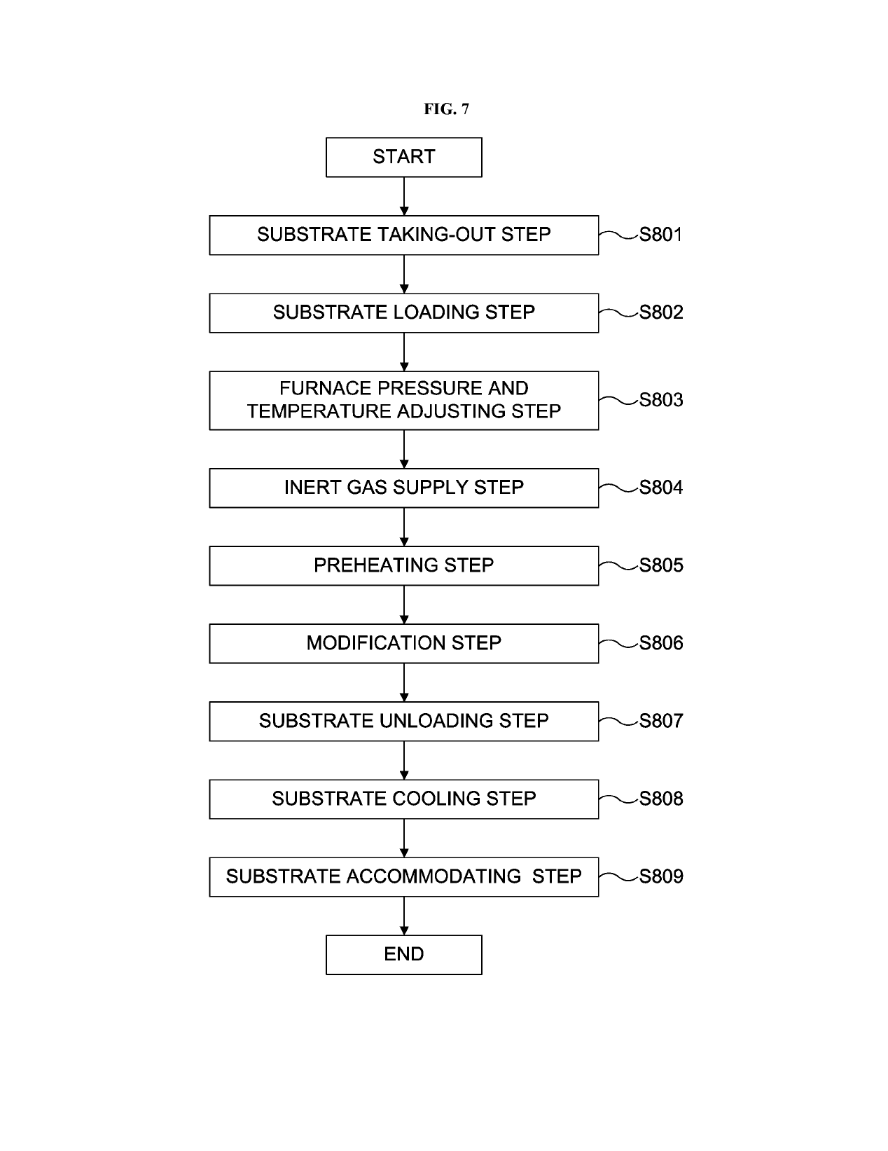

As a part of a manufacturing process of a semiconductor device, for example, a method of modifying (or crystallizing) a film to be processed (also referred to as a “target film”) FL1 formed on the wafer 200 is performed by using the process furnace of the substrate processing apparatus 100 described above. For example, the heat treatment process (modification process) is performed on the target film FL1 formed on the wafer 200. The method of modifying (crystallizing) the target film FL1 will be described with reference to an exemplary process flow shown in FIG. 7.

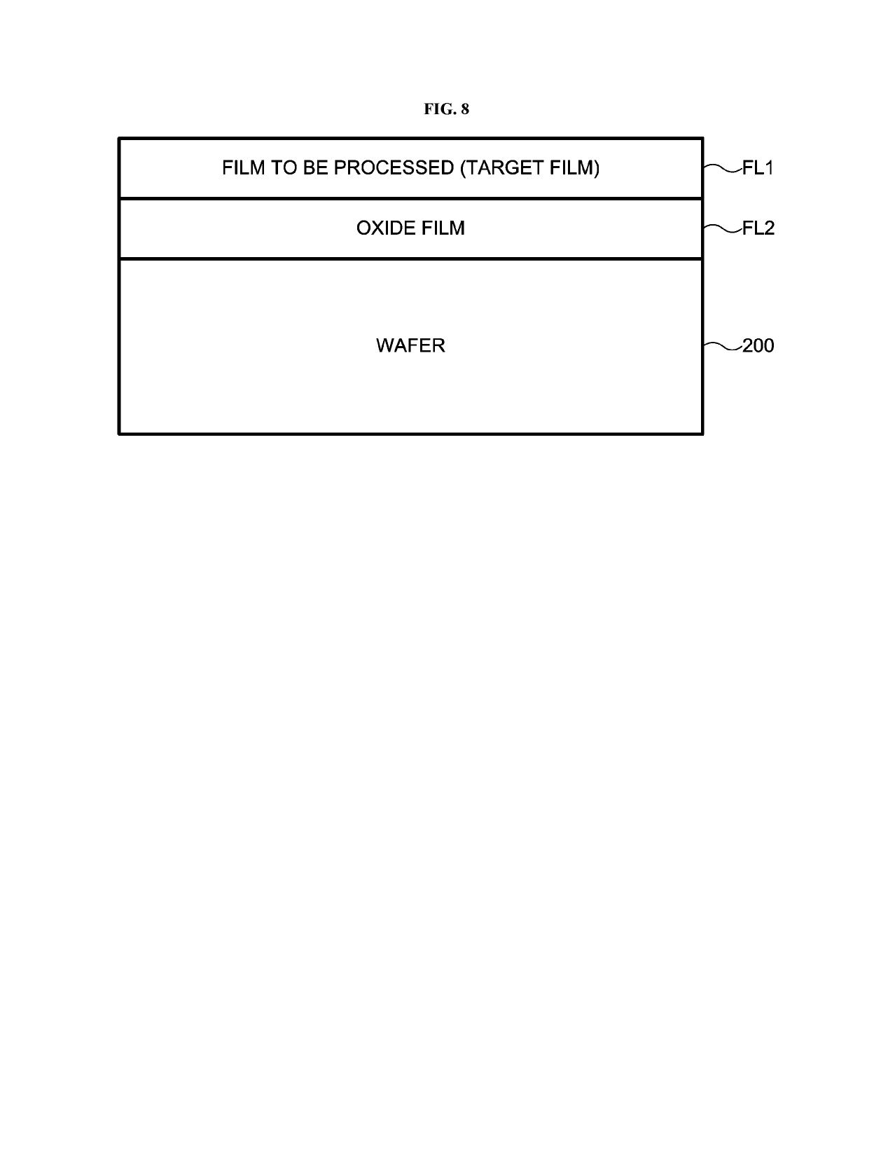

As shown in FIG. 8, the target film FL1 serving as a first film and a film not to be processed (also referred to as a “non-target film”) FL2 serving as a second film different from the first film are formed on the wafer 200. For example, the second film FL2 is an oxide film or a nitride film, and is formed between the wafer 200 and the first film FL1. For example, the target film FL1 is an amorphous silicon (Si) film to which a dopant (impurity) is added. For example, the dopant may contain phosphorus (P) or boron (B). In the present specification, a silicon film to which phosphorus is added (doped) may also be referred to as a “P-doped Si film.” For example, the non-target film FL2 is a silicon oxide film (SiO film) or a silicon nitride film (SiN film). The target film FL1 is a target film to be modified by the modification process using the electromagnetic wave.

An electromagnetic wave (microwave) absorption rate of the target film FL1 and an electromagnetic wave (microwave) absorption rate of the wafer 200 are different from each other depending on a process temperature. When the process temperature is between approximately 20 °C and 200 °C, the electromagnetic wave absorption rate of the target film FL1 is 0.20 %, while the electromagnetic wave absorption rate of the wafer 200 is 0.05 %. That is, a ratio of the electromagnetic wave absorption rate of the target film FL1 to the electromagnetic wave absorption rate of the wafer 200 is 4:1. Thus, when the ratio of the electromagnetic wave absorption rate of the target film FL1 (0.20 %) to the electromagnetic wave absorption rate of the wafer 200 (0.05 %) is 4:1, the electromagnetic wave absorption rate of the target film FL1 is higher than the electromagnetic wave absorption rate of the wafer 200. Thereby, it is possible to heat the target film FL1 while suppressing the heating of the wafer 200. When the process temperature is greater than 200 °C, the electromagnetic wave absorption rate of the wafer 200 increases. When the process temperature reaches 250 °C, the electromagnetic wave absorption rate of the target film FL1 remains unchanged at 0.20 %. However, the electromagnetic wave absorption rate of the wafer 200 becomes 0.20 %, the same as the electromagnetic wave absorption rate of the target film FL1. In such a case, the ratio of the electromagnetic wave absorption rate of the target film FL1 to the electromagnetic wave absorption rate of the wafer 200 becomes 1:1. In addition, when the process temperature reaches 250 °C, the electromagnetic wave absorption rate of the wafer 200 increases, and the wafer 200 is heated by the electromagnetic wave. When the process temperature is a low temperature around 200 °C, the non-target film FL2 does not absorb the electromagnetic wave, and is not processed. Thus, when the process temperature is set to 200 °C or less, the electromagnetic wave absorption rate of the target film FL1 is higher than that of the wafer 200. Therefore, it is possible to heat the target film FL1 to perform the modification process thereon while suppressing the heating of the wafer 200.

In the present specification, the term “process temperature” may refer to the “temperature of the wafer 200” or a “temperature (inner temperature) of the process chamber 201”, and the term “process pressure” may refer to the “inner pressure of the process chamber 201”. In addition, the term “process time” refers to a time duration of continuously performing a process related thereto. The same also applies to the following description.

For example, the SiO film is a film which is formed by creating an oxygen atmosphere in a reaction chamber and diffusing oxygen (O) onto a surface of a silicon substrate (that is, the surface of the wafer 200). Further, the P-doped Si film is a film into which phosphorus (P) is ion-implanted. The SiO film and the P-doped Si film described above are formed on the wafer 200 by using another substrate processing apparatus (which is different from the substrate processing apparatus 100 described above) such as a batch type substrate processing apparatus or an ion implantation apparatus.

In the following descriptions, operations of components constituting the substrate processing apparatus 100 are controlled by the controller 121. According to the present embodiments, processing contents of the substrate processing performed by the plurality of the process furnaces provided in the substrate processing apparatus 100 are substantially the same. That is, the same recipe is used in the plurality of the process furnaces to perform the substrate processing. Similar to the configurations of the plurality of the process furnaces described above, the substrate processing performed by one process furnace will be described and the detailed descriptions of the substrate processing performed by the other process furnaces will be omitted.

In the present specification, the term “wafer” may refer to “a wafer itself” or may refer to “a wafer and a stacked structure (aggregated structure) of a predetermined layer (or layers) or a film (or films) formed on a surface of the wafer.” In the present specification, “a surface of a wafer” may refer to “a surface of a wafer itself” or may refer to “a surface of a predetermined layer (or layers) or a film (or films) formed on a wafer.” Thus, in the present specification, “forming a predetermined layer (or a film) on a wafer” may refer to “forming a predetermined layer (or a film) directly on a surface of a wafer itself” or may refer to “forming a predetermined layer (or a film) on a surface of another layer or another film formed on the wafer.” In the present specification, the terms “substrate” and “wafer” may be used as substantially the same meaning.

First, after a substrate taking-out step S801 is performed, a substrate loading step S802 is performed. In the substrate loading step S802, the wafers 200 are transferred (loaded) into a predetermined process chamber, that is, the process chamber 201 (that is a boat loading is performed) while the gate valve 205 is opened by an opening and closing operation of the gate valve 205. That is, by using the tweezers 125a-1 used for transferring the wafer at the low temperature and the tweezers 125a-2 used for transferring the wafer at the high temperature, for example, two wafers placed on the tweezers 125a-1 and the tweezers 125a-2 are transferred (loaded) into the process chamber 201.

### Furnace Pressure and Temperature Adjusting Step S803

After the wafers 200 are loaded into the process chamber 201, the inner atmosphere of the process chamber 201 is controlled (adjusted) such that the inner pressure of the process chamber 201 reaches and is maintained at a predetermined pressure (for example, a pressure within a range from 10 Pa to 102,000 Pa). Specifically, the opening degree of the APC valve (that is, the pressure regulator 244) is feedback-controlled based on pressure information detected by the pressure sensor 245 to adjust the inner pressure of the process chamber 201 to the predetermined pressure while exhausting the process chamber 201 by the vacuum pump 246. In addition, the inner temperature of the process chamber 201 is adjusted to a predetermined temperature.

In the present specification, a notation of a numerical range such as “from 10 Pa to 102,000 Pa” means that a lower limit and an upper limit are included in the numerical range. Therefore, for example, the numerical range “from 10 Pa to 102,000 Pa” means a range equal to or higher than 10 Pa and equal to or lower than 102,000 Pa. The same also applies to other numerical ranges described in the present specification.

### Inert Gas Supply Step S804

After the inner pressure and the inner temperature of the process chamber 201 are respectively controlled to the predetermined values by the furnace pressure and temperature adjusting step S803, the driver 267 rotates the shaft 255 and rotates the wafers 200 via the boat 217 on the mounting table 210. While the driver 267 rotates the wafers 200, the inert gas such as the nitrogen gas is supplied into the process chamber 201 through the gas supply pipe 232 (step S804). In the inert gas supply step S804, for example, the inner pressure of the process chamber 201 is adjusted to a predetermined pressure within a range from 10 Pa to 102,000 Pa. For example, the inner pressure of the process chamber 201 is adjusted to a predetermined pressure within a range from 101,300 Pa to 101,650 Pa. Alternatively, the driver 267 may rotate the shaft 255 in the substrate loading step S802, that is, after the wafers 200 are loaded into the process chamber 201.

As the inert gas, in addition to or instead of the nitrogen (N₂) gas, a rare gas such as argon (Ar) gas, helium (He) gas, neon (Ne) gas and xenon (Xe) gas may be used.

### Preheating Step S805

Subsequently, when the inner pressure of the process chamber 201 reaches and is maintained at a predetermined pressure, the microwave oscillator 655 supplies the microwave into the process chamber 201 through the components described above such as the electromagnetic wave introduction port 653 and the waveguide 654. By setting an output of the microwave to be smaller than the output of the microwave in a modification step S806 described later, a preheating process (that is, the preheating step S805) of heating the wafers 200 is performed. Thereby, by slowing down an elevation of the temperature of the substrate (that is, the wafer 200), it is possible to prevent a warp or a crack of the wafer 200.

### Modification Step S806

While maintaining the inner pressure of the process chamber 201 at a predetermined pressure, the microwave oscillator 655 supplies the microwave into the process chamber 201 through the components described above such as the electromagnetic wave introduction port 653 and the waveguide 654 to process the wafer 200 (that is, to perform the modification process). The microwave is supplied by performing a microwave pulse irradiation. The microwave pulse irradiation is performed by repeatedly turning off a supply of the microwave before a thermal conduction and turning on the supply of the microwave in order to elevate the temperature and maintain the heating (thermal equilibrium). Since the turn-on time and the turn-off time of the supply of the microwave can be varied, it is possible to repeatedly perform the turn-on operation and the turn-off operation in a short period of time. The turn-on time of the microwave is preferably on the order of 1 microsecond. Thereby, it is possible to heat the wafer 200 such that the process temperature is maintained at a predetermined temperature of 200 °C or less. By heating the wafer 200 such that the process temperature is maintained at a predetermined temperature of 200°C or less in a manner described above, the electromagnetic wave absorption rate of the target film FL1 becomes higher than the electromagnetic wave absorption rate of the wafer 200. Thereby, it is possible to heat the target film FL1 to perform the modification process thereon while suppressing the heating of the wafer 200. In addition, the controller 121 is configured to be capable of controlling the microwave oscillator 655 such that the microwave pulse irradiation is started so as to heat the target film FL1 by the microwave pulse irradiation and such that the microwave pulse irradiation is repeatedly turned on and off in a short period of time for the process temperature to reach 200 °C.

For example, a frequency of a microwave power supply is set to 2.45 GHz. For example, the wafer 200 is heated by repeatedly supplying the microwave in a pulsed manner with the turn-off time of the supply of the microwave being longer than the turn-on time thereof a predetermined number of times or for a predetermined time duration. In the present step, the turn-on time is preferably greater than or equal to 0.6 microsecond and less than or equal to 10 microseconds. When the turn-on time is 0.6 microsecond or less, the heating may be insufficient and the dopant may not be activated. When the turn-on time is 10 microseconds or more, the heating due to the thermal conduction may be dominant. Therefore, the heat may be transferred to the wafer 200 and the non-target film FL2.

### Substrate Unloading Step S807

After returning the inner pressure of the process chamber 201 to an atmospheric pressure, the gate valve 205 is opened such that the process chamber 201 spatially communicates with the transfer chamber 203. Thereafter, the wafer 200 (which is processed (or heated) and then placed on the boat 217) is transferred (unloaded) to the transfer chamber 203 by the tweezers 125a-2 (which are used for transferring the wafer at the high temperature) of the transfer device 125 (step S807).

### Substrate Cooling Step S808

The wafer 200 (which is heated (processed) and then transferred by the tweezers 125a-2 used for transferring the wafer at the high temperature) is moved to the cooling chamber 204 by consecutive operations of the transfer structure 125b and the transfer structure elevator 125c. For example, two wafers 200 are placed in the cooling chamber 204 by the tweezers 125a-2 used for transferring the wafer at the high temperature. By placing the wafers 200 in the cooling chamber 204 for a predetermined time, it is possible to cool the wafers 200 (step S808).

### Substrate Accommodating Step S809

The two wafers 200 cooled by performing the substrate cooling step S808 are taken out from the cooling chamber 204, and then are transferred to and accommodated in a predetermined pod.

### Other Embodiments of Present Disclosure

While the embodiments mentioned above are described by way of an example in which the substrate processing is performed as a part of the manufacturing process of the semiconductor device, the technique of the present disclosure is not limited thereto. For example, the technique of the present disclosure may be applied to other substrate processing such as a patterning process in a manufacturing process of a liquid crystal panel, a patterning process in a manufacturing process of a solar cell and a patterning process in a manufacturing process of a power device.

In addition, the technique of the present disclosure is not limited to the embodiments mentioned above, and the technique of the present disclosure may be applied to various modified examples of the embodiments mentioned above. For example, the embodiments mentioned above are described in detail in order to explain the technique of the present disclosure in an easy-to-understand manner. That is, the technique of the present disclosure is not limited to those including an entirety of configurations of the embodiments mentioned above.

For example, the embodiments mentioned above are mainly described by way of an example in which the program for implementing an entirety of or a part of configurations or functions of the controller serving as the control structure is provided. However, for example, an entirety of or a part of functions of a processor serving as the controller may be implemented by a hardware by designing an integrated circuit to be used instead of the program. That is, the entirety of or the part of the functions of the processor may be implemented by using the integrated circuit such as an ASIC (Application Specific Integrated Circuit) and an FPGA (Field Programmable Gate Array) instead of the program.

For example, the embodiments mentioned above are described by way of an example in which a single wafer type substrate processing apparatus capable of processing one or several substrates at a time is used to form the film. However, the technique of the present disclosure is not limited thereto. For example, the technique of the present disclosure may be preferably applied when a batch type substrate processing apparatus capable of simultaneously processing a plurality of substrates is used to form the film. For example, the embodiments mentioned above are described by way of an example in which a substrate processing apparatus including a cold wall type process furnace is used to form the film. However, the technique of the present disclosure is not limited thereto. For example, the technique of the present disclosure may be preferably applied when a substrate processing apparatus including a hot wall type process furnace is used to form the film.

The process sequences and the process conditions of each process using the substrate processing apparatuses exemplified above may be substantially the same as those of the embodiments mentioned above. Even in such a case, it is possible to obtain substantially the same effects according to the embodiments mentioned above.

According to some embodiments of the present disclosure, it is possible to perform the modification process while suppressing a heat diffusion.

What is claimed is:

1. A substrate processing method comprising:
preparing a substrate provided with at least a first film formed thereon; and
modifying the substrate by supplying an electromagnetic wave to the substrate for a temperature of the substrate to be equal to or less than a predetermined temperature such that an absorption rate of the electromagnetic wave of the first film is higher than an absorption rate of the electromagnetic wave of the substrate.

2. The substrate processing method of claim 1, wherein the predetermined temperature is a temperature at which a ratio of the absorption rate of the electromagnetic wave of the first film to the absorption rate of the electromagnetic wave of the substrate is 4:1.

3. The substrate processing method of claim 1, wherein the predetermined temperature is set to 200 °C or less.

4. The substrate processing method of claim 1, wherein a second film different from the first film is formed on the substrate.

5. The substrate processing method of claim 4, wherein the second film is formed between the first film and the substrate.

6. The substrate processing method of claim 4, wherein the first film is a film doped with a dopant.

7. The substrate processing method of claim 6, wherein the dopant comprises phosphorus or boron.

8. The substrate processing method of claim 4, wherein the second film is a film not to be processed.

9. The substrate processing method of claim 4, wherein at least an oxide film or a nitride film is formed on the second film.

10. The substrate processing method of claim 1, wherein the first film is a target film to be processed by the electromagnetic wave.

11. The substrate processing method of claim 1, wherein the electromagnetic wave is supplied in a pulsed manner in which a supply of the electromagnetic wave is turned on for a first predetermined time and turned off for a second predetermined time.

12. The substrate processing method of claim 11, wherein the second predetermined time is set to be longer than the first predetermined time.

13. The substrate processing method of claim 11, wherein the first predetermined time and the second predetermined time are variable.

14. The substrate processing method of claim 11, wherein the first predetermined time is set to not less than 0.6 microseconds.

15. The substrate processing method of claim 1, wherein the electromagnetic wave comprises a microwave.

16. A method of manufacturing a semiconductor device, comprising:
the method of claim 1.

17. A substrate processing apparatus comprising:
a process chamber in which a substrate provided with at least a first film formed thereon is accommodated;
an electromagnetic wave supplier configured to supply an electromagnetic wave to the substrate; and
a controller configured to be capable of controlling the electromagnetic wave supplier to by supply the electromagnetic wave to the substrate for a temperature of the substrate to be equal to or less than a predetermined temperature such that an absorption rate of the electromagnetic wave of the first film is higher than an absorption rate of the electromagnetic wave of the substrate.

18. A non-transitory computer-readable recording medium storing a program that causes, by a computer, a substrate processing apparatus to perform:
preparing a substrate provided with at least a first film formed thereon; and
modifying the substrate by supplying an electromagnetic wave to the substrate for a temperature of the substrate to be equal to or less than a predetermined temperature such that an absorption rate of the electromagnetic wave of the first film is higher than an absorption rate of the electromagnetic wave of the substrate.
